(19) United States
(12) Patent Application Publication
(10) Pub. No.: US 2026/0329115 A1
(43) Pub. Date: Oct. 22, 2026

(54) SEMICONDUCTOR WAVEGUIDE HEATER WITH HEATER CONTACTS

(71) Applicant: Taiwan Semiconductor Manufacturing Company, Ltd., Hsinchu (TW)

(72) Inventors: Cheng-Tse Tang, Hsinchu County (TW); Hau-Yan Lu, Hsinchu City (TW); Wei-Kang Liu, Taichung City (TW); Yingkit Felix Tsui, Cupertino, CA (US)

(21) Appl. No.: 19/721,036

(22) Filed: Jun. 26, 2026

Related U.S. Application Data
(63) Continuation of application No. 18/630,307, filed on Apr. 9, 2024.

(51) Int. Cl. G02F 1/025; G02F 1/01; H10P 30/22; H10P 50/24

(52) U.S. Cl. CPC G02F 1/025; G02F 1/0147; H10P 30/22; H10P 50/242

(57) ABSTRACT

An integrated chip includes a substrate, a semiconductor waveguide layer, a conductive heater line, a first heater contact, and a second heater contact. The semiconductor waveguide layer is over the substrate. A base portion of the semiconductor waveguide layer extends laterally over the substrate. A ridge portion of the semiconductor waveguide layer protrudes upward from the base portion. The conductive heater line is spaced over the ridge portion of the semiconductor waveguide layer. The first heater contact and the second heater contact extend from the conductive heater line to the base portion of the semiconductor waveguide layer on opposite sides of the ridge portion of the semiconductor waveguide layer.

### REFERENCE TO RELATED APPLICATION

This Application is a Continuation of U.S. Application number 18/630,307, filed on Apr. 9, 2024, the contents of which are hereby incorporated by reference in their entirety.

### BACKGROUND

Optical waveguides are often used as components in integrated optical circuits. Optical waveguides are used to confine and guide light from a first point on an integrated chip (IC) to a second point on the IC with minimal attenuation. Many modern optical waveguides are formed using semiconductors. A semiconductor waveguide may include an optical converter or an optical coupler for optically coupling an optical fiber to the semiconductor waveguide.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of a photonic integrated chip comprising a heater over and contacting a waveguide.

FIG. 2 illustrates a top view of some embodiments of the photonic integrated chip of FIG. 1.

FIGS. 3-6 illustrate cross-sectional views of some other embodiments of the photonic integrated chip of FIG. 1.

FIG. 7 illustrates a cross-sectional view of some embodiments of the photonic integrated chip of FIG. 1 in which the waveguide forms a micro-ring modulator.

FIG. 8 illustrates a top view of some embodiments of the photonic integrated chip of FIG. 7.

FIG. 9 illustrates a cross-sectional view of some embodiments of the photonic integrated chip of FIG. 1 in which the waveguide forms a Mach-Zehnder modulator.

FIG. 10 illustrates a top view of some embodiments of the photonic integrated chip of FIG. 9.

FIGS. 11-26 illustrate cross-sectional views of some embodiments of a method for forming a photonic integrated chip comprising a heater over and contacting a waveguide.

FIG. 27 illustrates a flow diagram of some embodiments of a method for forming a photonic integrated chip comprising a heater over and contacting a waveguide.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A photonic integrated chip includes a waveguide over a substrate. The waveguide is formed by a semiconductor waveguide layer. A base portion of the semiconductor waveguide layer extends laterally over the substrate and a ridge portion of the semiconductor waveguide layer protrudes upward from the base portion. Optical radiation (e.g., optical signals) travels through the semiconductor waveguide layer. In some cases, a majority of the optical radiation traveling through the semiconductor waveguide layer is confined within the ridge portion of the semiconductor waveguide layer.

The performance of the semiconductor waveguide layer can be affected by the temperature of the semiconductor waveguide layer. For example, the phase of the optical signal(s) traveling through the semiconductor waveguide layer can be affected by the temperature of the semiconductor waveguide layer. Thus, a heater is arranged over the semiconductor waveguide layer to control a temperature of the semiconductor waveguide layer. The heater is formed by a conductive heater line. The conductive heater line is over the ridge portion of the semiconductor waveguide layer. In some cases, the heater may cause optical radiation loss in the semiconductor waveguide layer if the heater is too close to the ridge. Thus, the conductive heater line is spaced from the ridge. Current is passed through the conductive heater line to increase the temperature of the conductive heater line. The temperature of the conductive heater line can be controlled by controlling the current. The heat emitted from the conductive heater line heats the semiconductor waveguide layer. By controlling the temperature of the semiconductor waveguide layer with the heater, a control of the performance of the waveguide may be improved.

One challenge with the heater is that the sides of the ridge portion of the semiconductor waveguide layer have less exposure to the heat from the heater than to the top of the ridge portion of the semiconductor waveguide layer. Thus, the control of the temperature of the sides of the ridge portion of the semiconductor waveguide layer may be reduced. Another challenge with the heater is that the spacing between the heater and the semiconductor waveguide layer may inhibit thermal transfer from the conductive heater line to the semiconductor waveguide layer. Thus, the control of the temperature of the semiconductor waveguide layer may be further reduced.

In various embodiments of the present disclosure, the heater is further formed by a first heater contact and a second heater contact which extend from the conductive heater line to the base portion of the semiconductor waveguide layer on opposite sides of the ridge portion of the semiconductor waveguide layer. The first and second heater contacts contact the base portion of the semiconductor waveguide layer and are laterally spaced from the ridge portion of the semiconductor waveguide layer by a substantial distance.

Because the heater contacts extend along sides of the ridge portion of the semiconductor waveguide layer, the ridge portion has increased exposure to the heater. Thus, the control of the temperature of the ridge portion can be improved and hence the control of the performance of the waveguide can be improved. Further, because the heater contacts directly contact the base portion of the semiconductor waveguide layer, the thermal transfer from the heater to the semiconductor waveguide layer can be improved. Thus, the control of the temperature of the semiconductor waveguide layer can be further improved. Furthermore, because the heater contacts are spaced from the ridge portion by a substantial distance, the likelihood that the heater causes optical radiation loss along the semiconductor waveguide layer can be reduced.

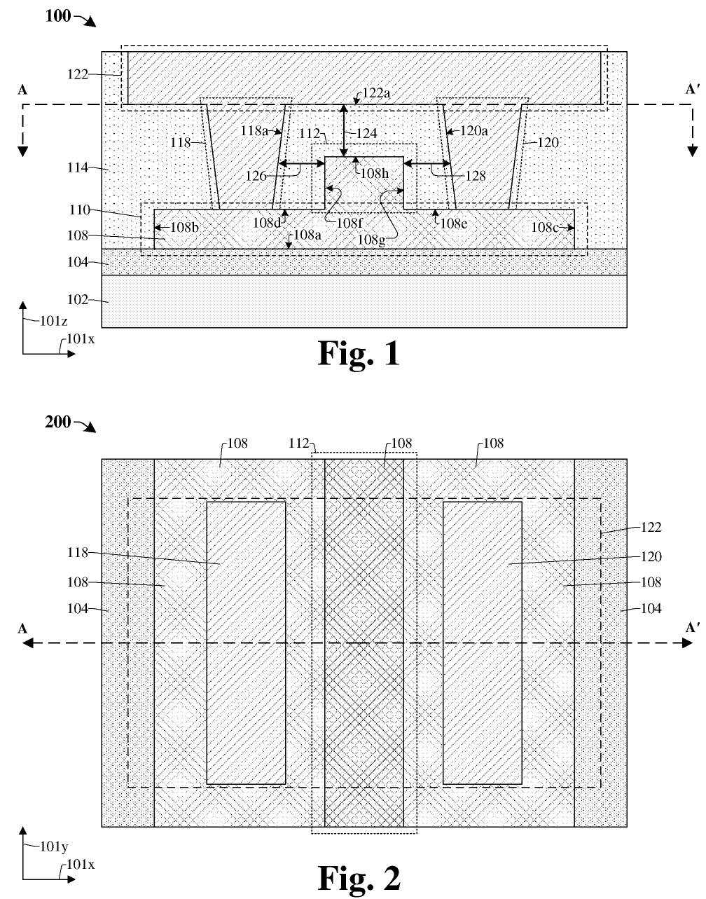

FIG. 1 illustrates a cross-sectional view 100 of some embodiments of a photonic integrated chip comprising a heater over and contacting a waveguide.

The integrated chip comprises a base semiconductor layer 102 and a base dielectric layer 104 over the base semiconductor layer 102. In some embodiments, the base semiconductor layer 102 and the base dielectric layer 104 are referred to as a substrate.

A semiconductor waveguide layer 108 is over the base dielectric layer 104. The semiconductor waveguide layer 108 forms the waveguide. A base portion 110 of the semiconductor waveguide layer 108 extends laterally along a top surface of the base dielectric layer 104. The base portion 110 is delimited by a bottom surface 108a, a first sidewall 108b, a second sidewall 108c, a first upper surface 108d, and a second upper surface 108e of the semiconductor waveguide layer 108. A ridge portion 112 of the semiconductor waveguide layer 108 protrudes upward from the base portion 110. The ridge portion 112 is delimited by a third sidewall 108f, a fourth sidewall 108g, and a top surface 108h of the semiconductor waveguide layer 108.

A heater is disposed over the semiconductor waveguide layer 108. The heater is formed by a conductive heater line 122, a first conductive heater contact 118, and a second conductive heater contact 120. The heater line 122 is spaced over the semiconductor waveguide layer 108. The heater line 122 extends laterally over the base portion 110 and the ridge portion 112 of the semiconductor waveguide layer 108. The first heater contact 118 and the second heater contact 120 extend from the heater line 122 to the base portion 110 of the semiconductor waveguide layer 108 on opposite sides of the ridge portion 112 of the semiconductor waveguide layer 108. The first heater contact 118 contacts the first upper surface 108d of the semiconductor waveguide layer 108 and is laterally spaced from the ridge portion 112 in a first direction. The second heater contact 120 contacts the second upper surface 108e of the semiconductor waveguide layer 108 and is laterally spaced from the ridge portion 112 in a second direction opposite the first direction.

A dielectric structure 114 comprising one or more dielectric layers is over the semiconductor waveguide layer 108 and surrounds the heater contacts 118, 120, the heater line 122, and the semiconductor waveguide layer 108. The dielectric structure 114 is directly between the semiconductor waveguide layer 108 and the heater line 122 and directly between the semiconductor waveguide layer 108 and the heater contacts 118, 120. The dielectric structure 114 is or comprises a cladding layer which further forms the waveguide.

Because the heater contacts 118, 120 extend along sides of the ridge portion 112 of the semiconductor waveguide layer 108 (e.g., where a majority of the optical radiation is often confined), the ridge portion 112 has increased exposure to the heater. Thus, the control of the temperature of the ridge portion 112 can be improved. Further, because the heater contacts 118, 120 contact the base portion 110 of the semiconductor waveguide layer 108, the thermal transfer from the heater to the semiconductor waveguide layer 108 can be improved. Thus, the control of the temperature of the semiconductor waveguide layer 108 can be further improved. Furthermore, the heater is spaced from the ridge portion 112 by a substantial distance to reduce the likelihood that the heater causes optical radiation loss along the semiconductor waveguide layer 108.

The spacing between the ridge portion 112 and the heater (e.g., the heater line 122 and the heater contacts 118, 120) is large enough to reduce or prevent substantial optical loss along the semiconductor waveguide layer 108. For example, the distance 124 between a bottom surface 122a of the heater line 122 and top surface 108h of the semiconductor waveguide layer 108, the distance 126 between sidewall 108f of the semiconductor waveguide layer 108 and sidewall 118a of the first heater contact 118, and the distance 128 between sidewall 108g of the semiconductor waveguide layer 108 and sidewall 120a of the second heater contact 120 are at least 100 nanometers, at least 500 nanometers, at least 1 micrometer, at least 5 micrometers, or some other suitable distance. In some embodiments, distance 124, distance 126, and distance 128 range from 100 nanometers to 10 micrometers, from 500 nanometers to 5 micrometers, from 1 micrometer to 2 micrometers, or some other suitable range.

In some embodiments, the base semiconductor layer 102 comprises silicon or some other suitable semiconductor. In some embodiments, the base dielectric layer 104 comprises silicon dioxide or some other suitable dielectric. In some embodiments, the semiconductor waveguide layer 108 comprises intrinsic (e.g., undoped) silicon or some other suitable semiconductor. In some embodiments, the heater line 122 and the heater contacts 118, 120 comprise one or more metals such as, for example, copper, aluminum, titanium nitride, tungsten, or some other suitable materials.

In some embodiments, the dielectric layer(s) of the dielectric structure 114 comprise silicon dioxide, silicon nitride, silicon carbide, silicon oxynitride, silicon carbonitride, silicon oxycarbide, or some other suitable material. In some embodiments, the heat capacity of the region between the heater and the waveguide can be tuned by adjusting the dielectric material that is between the waveguide and the heater. For example, in some embodiments, a first dielectric having a first heat capacity is between the heater and the waveguide. In some other embodiments, a second dielectric having a second heat capacity, different than the first heat capacity, is between the heater and the waveguide. By tuning the heat capacity in the spacing between the heater and the waveguide, the control of the temperature of the semiconductor waveguide layer 108 can be further improved.

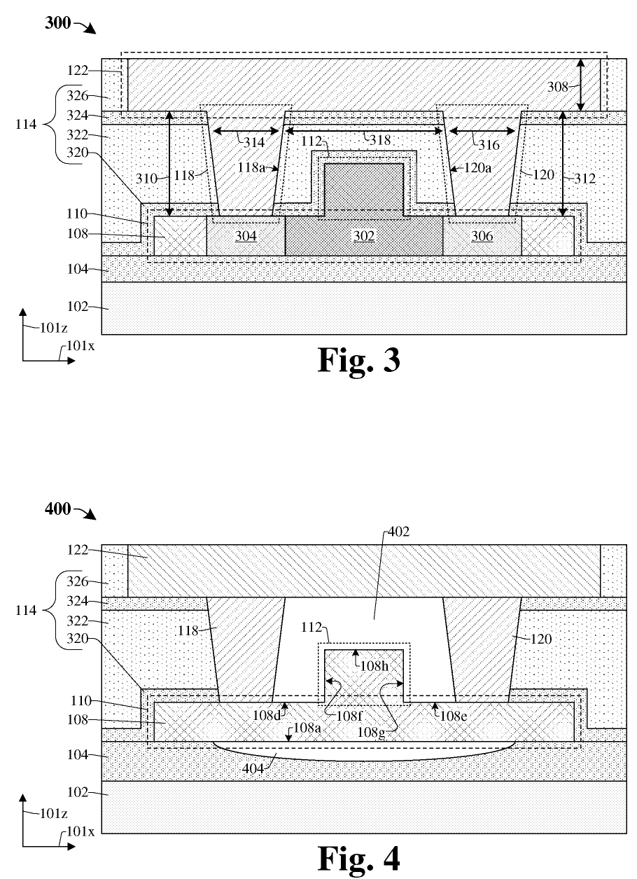

FIG. 2 illustrates a top view 200 of some embodiments of the photonic integrated chip of FIG. 1. In some embodiments, cross-sectional view 100 of FIG. 1 is taken across line A-A′ of FIG. 2. The dielectric structure 114 is not shown in FIG. 2 and the heater line 122 is shown “in phantom” (e.g., by a dashed line) in FIG. 2 for clarify of illustration of underlying layers.

The base portion 110 and the ridge portion 112 of the semiconductor waveguide layer 108 are elongated in direction 101y. In some embodiments, the heater contacts 118, 120, and the heater line 122 are also elongated in direction 101y along a portion of the length of the ridge portion 112. In some embodiments, the length (along direction 101y) of the heater line 122 is approximately equal to the length (along direction 101y) of the heater contacts 118, 120. In some embodiments, the width (along direction 101x) of the heater line 122 is greater than the width (along direction 101x) of the semiconductor waveguide layer 108.

FIG. 3 illustrates a cross-sectional view 300 of some embodiments of the photonic integrated chip of FIG. 1 in which regions of the semiconductor waveguide layer 108 are doped.

A first doped region 302 of the semiconductor waveguide layer 108 has a first doping type. The first doped region 302 is in the ridge portion 112 and the part of the base portion 110 directly under the ridge portion 112. Further, the first doped region 302 is in the base portion 110 on opposite sides of the ridge portion 112. A second doped region 304 and a third doped region 306 of the semiconductor waveguide layer 108 have the first doping type. The second doped region 304 is in the base portion 110 directly under the first heater contact 118. The third doped region 306 is in the base portion 110 directly under the second heater contact 120.

The doping concentrations of the second doped region 304 and the third doped region 306 are greater than the doping concentration of the first doped region 302. For example, the doping concentrations of the second doped region 304 and the third doped region 306 range from 10¹⁶ cm⁻³ to 10¹⁹ cm⁻³, 10¹⁷ cm⁻³ to 10¹⁸ cm⁻³, or some other suitable range, and the doping concentration of the first doped region 302 ranges from 10¹³ cm⁻³ to 10¹⁵ cm⁻³, 10¹⁴ cm⁻³ to 10¹⁵ cm⁻³, or some other suitable range.

By including the second and third doped regions 304, 306 having the higher doping concentrations where the heater contacts 118, 120 contact the semiconductor waveguide layer 108, a contact resistance between the heater contacts 118, 120 and the semiconductor waveguide layer 108 can be reduced. By reducing the contact resistance, thermal transfer and heating efficiency can be improved. Further, by including the first doped region 302 having the lower doping concentration along the ridge portion 112, a resistance at the ridge portion 112 can be tuned to reduce optical loss along the ridge portion 112.

In some embodiments, the first doping type is p type doping. In some other embodiments, the first doping type is n type doping.

In some embodiments, a thickness 308 (along direction 101z) of the heater line 122 ranges from 10 nanometers to 5 micrometers, 500 nanometers to 2.5 micrometers, or some other suitable range. In some embodiments, thicknesses 310, 312 (along direction 101z) of the heater contacts 118, 120 ranges from 10 nanometers to 5 micrometers, from 500 nanometers to 2.5 micrometers, or some other suitable range. In some embodiments, widths 314, 316 (along direction 101x) of the heater contacts 118, 120 ranges from 100 nanometers to 20 micrometers, 500 nanometers to 10 micrometers, or some other suitable range. In some embodiments, a distance 318 (along direction 101x) between the heater contacts (e.g., the distance between sidewall 118a and sidewall 120a) ranges from 100 nanometers to 10 micrometers, 500 nanometers to 5 micrometers, or some other suitable range.

In some embodiments, the dielectric structure 114 comprises a first etch stop layer 320 over the semiconductor waveguide layer 108, a first dielectric layer 322 over the first etch stop layer 320, a second etch stop layer 324 over the first dielectric layer 322, and a second dielectric layer 326 over the second etch stop layer 324. The heater line 122 extends along a top surface of the second etch stop layer 324. The second etch stop layer 324 is directly between the heater line 122 and the ridge portion 112. The heater contacts 118, 120 extend through the second etch stop layer 324 and the first dielectric layer 322 to the semiconductor waveguide layer 108.

In some embodiments, the heater is formed by a dual damascene process where the heater line 122 and the heater contacts 118, 120 are formed together with a common deposition process.

In some embodiments, the first etch stop layer 320 and the second etch stop layer 324 comprise silicon nitride, silicon carbide, silicon carbonitride, silicon oxycarbide, or some other suitable material. In some embodiments, the first dielectric layer 322 and the second dielectric layer 326 comprise silicon dioxide, silicon nitride, or some other suitable material.

FIG. 4 illustrates a cross-sectional view 400 of some embodiments of the photonic integrated chip of FIG. 1 in which an upper cavity 402 and a lower cavity 404 surround the waveguide.

The upper cavity 402 is between the ridge portion 112 and the heater. The upper cavity 402 is delimited by bottom surface 122a of the heater line 122, sidewall 118a of the first heater contact 118, and sidewall 120a of the second heater contact 120. In some embodiments, sidewalls (e.g., sidewalls 108f, 108g) and upper surfaces (e.g., top surface 108h and upper surfaces 108d, 108e) of the semiconductor waveguide layer 108 further delimit the upper cavity 402. In some other embodiments, the first etch stop layer 320 remains over the ridge portion 112 and thus sidewalls and upper surfaces of the first etch stop layer 320 further delimit the upper cavity 402. The upper cavity 402 is filled with air or the like. Air has a higher heat capacity than the dielectric (e.g., silicon dioxide or the like) of the dielectric structure 114. Thus, the upper cavity 402 can be formed between the heater and the waveguide to adjust the heat capacity of the spacing between the heater and the waveguide. As a result, the temperature control of the waveguide can be further tuned.

In some embodiments, a lower cavity 404 is directly below the semiconductor waveguide layer 108. The lower cavity 404 is delimited by the bottom surface 108a of the semiconductor waveguide layer 108 and by one or more surfaces of the base dielectric layer 104. The lower cavity 404 is directly below the ridge portion 112 and is filled with air or the like. The lower cavity 404 can be formed below the waveguide adjust the heat capacity of the area below the ridge portion 112. As a result, the temperature control of the waveguide can be further tuned.

In some embodiments, the heater is formed by a single damascene process where the heater contacts 118, 120 are formed separately from the heater line 122. In some such embodiments, the heater contacts 118, 120 may comprise a different conductive material than the heater line 122.

FIG. 5 illustrates a cross-sectional view 500 of some embodiments of the photonic integrated chip of FIG. 1 in which an active device is disposed along the waveguide.

The active device is formed by a first doped region 502 having a first doping type (e.g., p type), and a second doped region 504 having a second doping type (e.g., n type), different than the first doping type. In some embodiments, the active device is further formed by an intrinsic region 506 between the first doped region 502 and the second doped region 504. The first doped region 502, the second doped region 504, and the intrinsic region 506 form a p-i-n device in the semiconductor waveguide layer 108. The p-i-n device may, for example, convert optical signals traveling through the waveguide into electrical signals.

The intrinsic region 506 is in the ridge portion 112 and the part of the base portion 110 directly under the ridge portion 112. The first doped region 502 and the second doped region 504 are in the base portion 110 on opposite sides of the intrinsic region 506. In some embodiments, a first contact region 508 having the first doping type is in the first doped region 502 and a second contact region 510 having the second doping type is in the second doped region 504. The contact regions 508, 510 have higher doping concentrations than their corresponding doped regions 502, 504 to reduce contact resistance between the heater contacts 118, 120 and the semiconductor waveguide layer 108.

To prevent an electrical short between the first doped region 502 and the second doped region 504 of the active device, the heater line 122 comprises two separate conductive lines 512, 514. The first conductive line 512 is laterally spaced from, and electrically isolated from, the second conductive line 514. The dielectric structure 114 is directly between the conductive lines 512, 514. In some embodiments, the separation between the conductive lines 512, 514 is laterally offset from the ridge portion 112 (e.g., not directly over the ridge portion 112) so that the heater line 122 extends directly over the entirety of the top of the ridge portion 112 to maintain temperature control of the ridge portion 112.

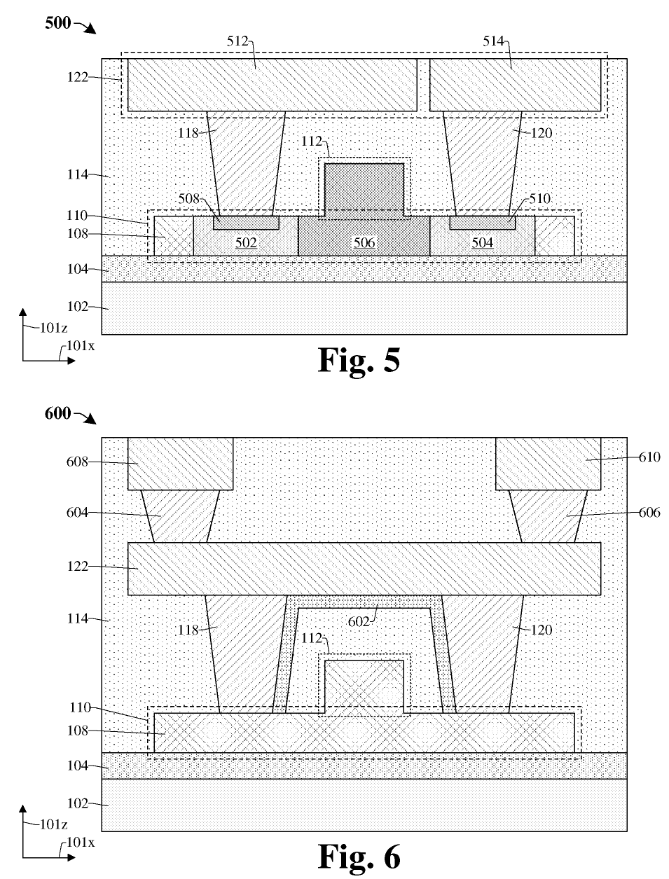

FIG. 6 illustrates a cross-sectional view 600 of some embodiments of the photonic integrated chip of FIG. 1 in which a barrier layer 602 is directly between the heater and the ridge portion 112.

The barrier layer 602 lines the inner sidewalls (e.g., sidewalls 118a, 120a) of the heater contacts 118, 120 and the bottom surface 122a of the heater line 122. The barrier layer 602 is included in the integrated chip to reduce a likelihood of electromigration from the heater contacts 118, 120 and/or the heater line 122 toward the ridge portion 112 (e.g., to prevent the distance between heater and the ridge portion 112 from being reduced). Thus, a likelihood of optical loss caused by the heater due to the distance between the heater and the waveguide being shortened over time by electromigration can be reduced.

In some embodiments, a plurality of conductive interconnects are over and coupled to the heater. For example, conductive vias 604, 606 are on the heater line 122 and conductive lines 608, 610 are on the conductive vias 604, 606, respectively. Current may be passed through the heater from one line/via (e.g., line 608 and via 604) to the other via/line (e.g., via 606 and line 610).

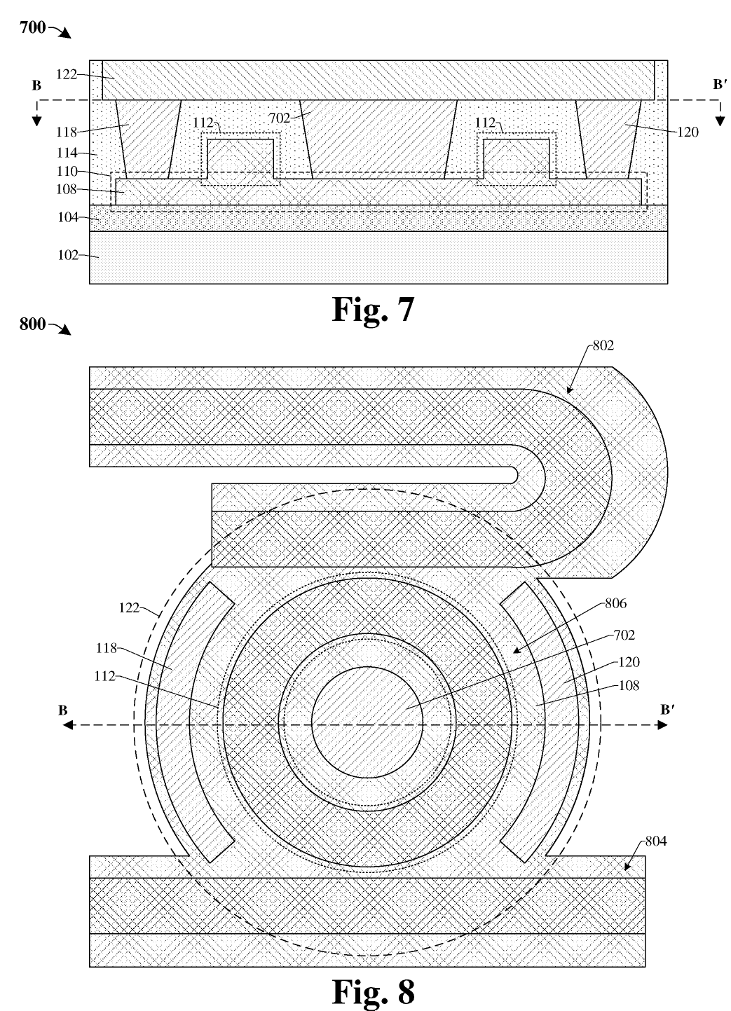

FIG. 7 illustrates a cross-sectional view 700 and FIG. 8 illustrates a top view 800 of some embodiments of the photonic integrated chip of FIG. 1 in which the semiconductor waveguide layer 108 forms a micro-ring modulator 806. In some embodiments, cross-sectional view 700 of FIG. 7 is taken across line B-B′ of FIG. 8. The heater line 122 is shown “in phantom” in FIG. 8 for clarity of illustration of underlying layers. The dielectric structure 114, the base dielectric layer 104, and the base semiconductor layer 102 are not shown in FIG. 8.

The ridge portion 112 extends in a closed ring. The base portion 110 surrounds the ring. The first heater contact 118 and the second heater contact 120 contact the base portion 110 outside of the ring. A third heater contact 702 contacts the base portion 110 inside the ring around the center of the ring. The heater line 122 extends over the ring and is coupled to the heater contacts 118, 120, 702. The micro-ring modulator modulates optical signals traveling through neighboring waveguides 802, 804.

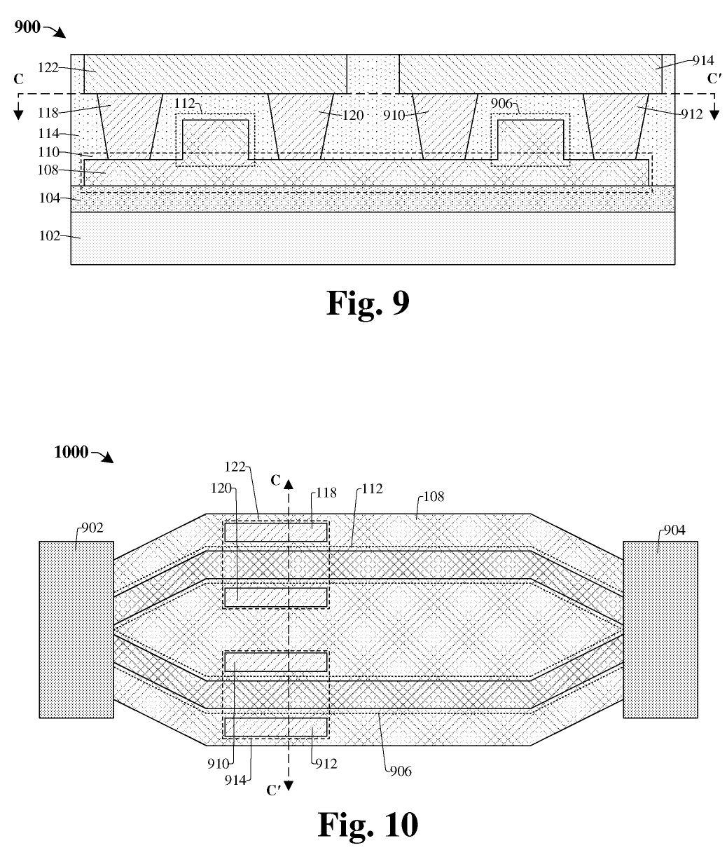

FIG. 9 illustrates a cross-sectional view 900 and FIG. 10 illustrates a top view 1000 of some embodiments of the photonic integrated chip of FIG. 1 in which the semiconductor waveguide layer 108 forms a Mach-Zehnder modulator. In some embodiments, cross-sectional view 900 of FIG. 9 is taken across line C-C′ of FIG. 10. Heater line 122 and heater line 914 are shown “in phantom” in FIG. 9 for clarity of illustration of underlying layers. The dielectric structure 114, the base dielectric layer 104, and the base semiconductor layer 102 are not shown in FIG. 9.

The waveguide has a second ridge portion 906 separate from ridge portion 112. The ridge portions 112, 906 extend between a first splitter 902 and a second splitter 904. The ridge portions split from one another at the splitters 902, 904. A second heater is over the second ride portion 906. The heaters are over a heater section of the modulator for tuning of the operation of the modulator. Adjacent to the heater section of the modulator is a phase shifter section of the modulator where high speed modulation can occur. The second heater is formed by a third heater contact 910, a fourth heater contact 912, and second heater line 914. The second heater is spaced from the first heater. For example, the second heater line 914 is spaced from heater line 122 and heater contacts 910, 912 are spaced from heater contacts 118, 120. The second heater is electrically isolated from the first heater so that each heater can be controlled independently. Thus, the temperature of each ridge portion in the modulator can be tuned separately. As a result, a control of the performance of the modulator can be improved.

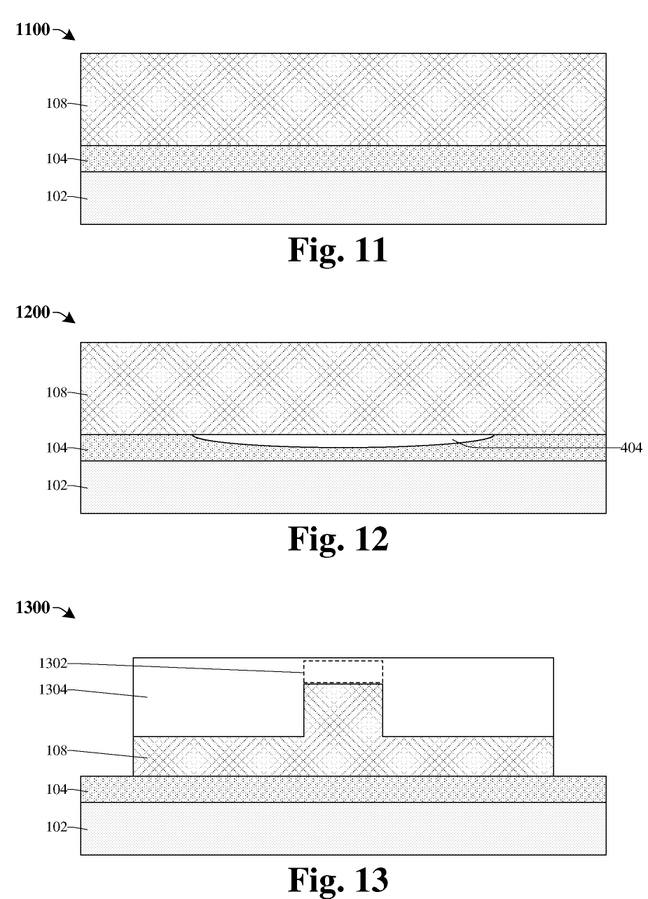

FIGS. 11-26 illustrate cross-sectional views 1100-2600 of some embodiments of a method for forming a photonic integrated chip comprising a heater over and contacting a waveguide. Although FIGS. 11-26 are described in relation to a method, it will be appreciated that the structures disclosed in FIGS. 11-26 are not limited to such a method, but instead may stand alone as structures independent of the method.

As shown in cross-sectional view 1100 of FIG. 11, the base semiconductor layer 102, the base dielectric layer, and a semiconductor waveguide layer 108 are provided. In some embodiments, the base semiconductor layer 102, the base dielectric layer 104, and the semiconductor waveguide layer 108 are a semiconductor-on-insulator (SOI) substrate.

As shown in cross-sectional view 1200 of FIG. 12, in some embodiments, a lower cavity 404 is formed in the base dielectric layer 104 below the semiconductor waveguide layer 108. In some embodiments, the lower cavity 404 is formed by etching the base dielectric layer 104 before the semiconductor waveguide layer 108 is formed on the base dielectric layer 104. In some other embodiments, forming the lower cavity 404 comprises forming a sacrificial layer (not shown) in the base dielectric layer 104 and removing the sacrificial layer after the semiconductor waveguide layer 108 is formed on the base dielectric layer 104. FIGS. 13-26 do not show the lower cavity 404.

As shown in cross-sectional view 1300 of FIG. 13, the semiconductor waveguide layer 108 is etched to form the waveguide from the semiconductor waveguide layer 108. In some embodiments, a first masking layer 1302 is formed over the semiconductor waveguide layer 108 and the semiconductor waveguide layer 108 is etched according to the first masking layer 1302 with a first etching process to delimit the ridge portion 112 and the base portion 110. Further, a second masking layer 1304 is formed over the semiconductor waveguide layer 108 after the first etching process and the semiconductor waveguide layer 108 is etched according to the second masking layer 1304 with a second etching process to further delimit the base portion 110.

In some embodiments, the first masking layer 1302 and the second masking layer 1304 comprise photoresist or some other suitable material. In some embodiments, the first etching process and the second etching process comprise a dry etching process such as, for example, a plasma etching process, a reactive ion etching process, an ion beam etching process, or some other suitable process.

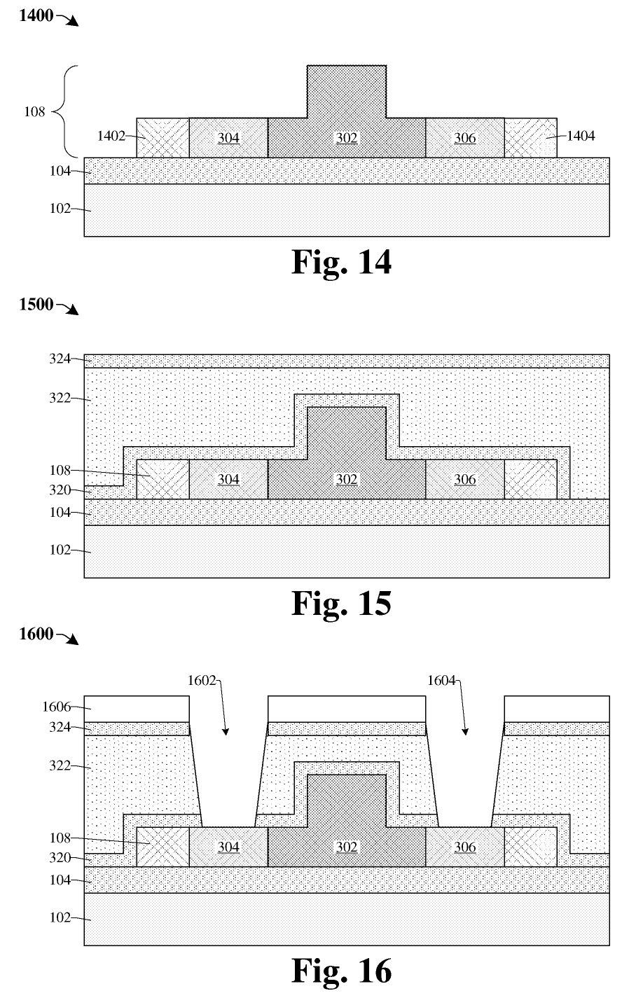

As shown in cross-sectional view 1400 of FIG. 14, in some embodiments, the semiconductor waveguide layer 108 is doped to form a first doped region 302, a second doped region 304, and a third doped region 306 in the semiconductor waveguide layer 108. In some embodiments, one or more intrinsic regions (e.g., intrinsic regions 1402, 1404) remain in the semiconductor waveguide layer 108 after the doping. In some other embodiments, the second doped region 304 and the third doped region 306 extend in opposite directions from the first doped region 302 to the outermost sidewalls of the semiconductor waveguide layer 108.

In some embodiments, the first doped region 302 is formed by forming a masking layer (not shown) over parts of the base portion 110 and performing a doping process such as, for example, ion implantation or some other suitable process with the masking layer in place. In some embodiments, the second doped region 304 and the third doped region 306 are formed by forming a masking layer (not shown) over the ridge portion 112 and parts of the base portion 110 and performing a doping process with the masking layer in place.

In some embodiments, the first doped region 302, the second doped region 304, and the third doped region 306 have a same doping type. Further, the second doped region 304 and the third doped region 306 have higher doping concentrations than the first doped region 302.

In some other embodiments, the semiconductor waveguide layer 108 is doped to form an active device along the semiconductor waveguide layer 108. For example, a first doped region (e.g., doped region 502 of FIG. 5) having a first doping type (e.g., p type), and a second doped region (e.g., doped region 504 of FIG. 5) having a second doping type (e.g., n type), different than the first doping type are formed on opposite sides of an intrinsic region (e.g., intrinsic region 506 of FIG. 5) to form a p-i-n device in the semiconductor waveguide layer 108.

FIGS. 15-21 illustrate cross-sectional views 1500-2100 of some embodiments of a method for forming the heater over the waveguide. The method illustrated in FIGS. 15-21 may be referred to as a single damascene type method.

As shown in cross-sectional view 1500 of FIG. 15, a first etch stop layer 320 is conformally deposited over the semiconductor waveguide layer 108, a first dielectric layer 322 is deposited over the first etch stop layer 320, and a second etch stop layer 324 is deposited over the first dielectric layer 322.

In some embodiments, the first etch stop layer 320 and the second etch stop layer 324 comprise silicon nitride, silicon carbide, silicon carbonitride, silicon oxycarbide, or some other suitable material and are deposited by chemical vapor deposition (CVD) processes, physical vapor deposition (PVD) processes, atomic layer deposition (ALD) processes, or some other suitable processes. In some embodiments, the first dielectric layer 322 comprises silicon dioxide, silicon nitride, or some other suitable material and is deposited by a CVD process, a PVD process, an ALD process, or some other suitable process. In some embodiments, the first etch stop layer 320 is omitted and the first dielectric layer 322 is deposited directly on semiconductor waveguide layer 108.

As shown in cross-sectional view 1600 of FIG. 16, the second etch stop layer 324, the first dielectric layer 322, and the first etch stop layer 320 are etched to form a first opening 1602 and a second opening 1604 in the second etch stop layer 324, the first dielectric layer 322, and the first etch stop layer 320. The first opening 1602 and the second opening 1604 uncover parts of the base portion 110 (e.g., where the second and third doped regions 304, 306 are located) on opposite sides of the ridge portion 112.

In some embodiments, a masking layer 1606 is formed over the second etch stop layer 324 and the etching is performed according to the masking layer 1606. In some embodiments, the masking layer 1606 comprises photoresist or some other suitable material. In some embodiments, the etching comprises a dry etching or some other suitable process.

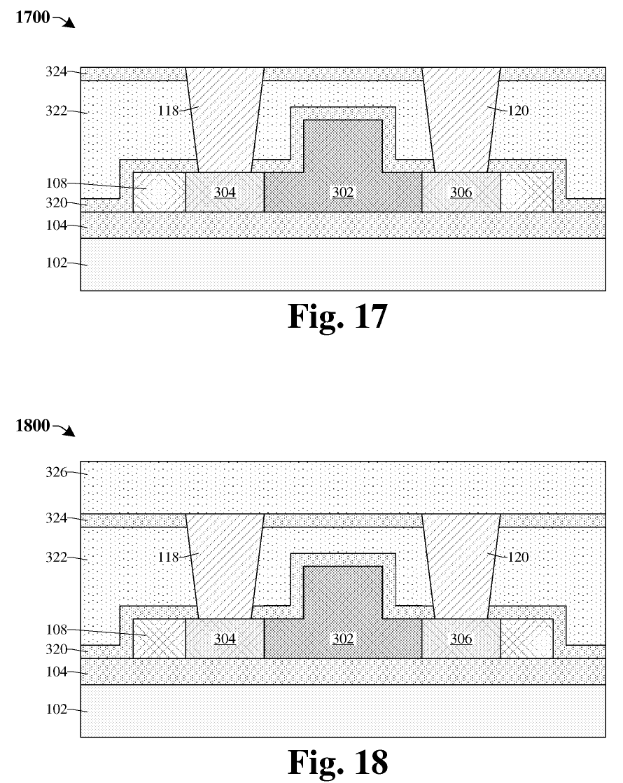

As shown in cross-sectional view 1700 of FIG. 17, the first heater contact 118 is formed in the first opening 1602 and the second heater contact 120 is formed in the second opening 1604. The first heater contact 118 and the second heater contact 120 contact the base portion 110 of the semiconductor waveguide layer 108 (e.g., at the second doped region 304 and the third doped region 306, respectively) on opposite sides of the ridge portion 112.

In some embodiments, the first heater contact 118 and the second heater contact 120 are formed by depositing a conductive material (e.g., copper, aluminum, titanium nitride, tungsten, or some other suitable material) over the second etch stop layer 324 and in the first and second openings 1602, 1604, and performing a planarization process (e.g., a chemical mechanical planarization (CMP) process, a blanket etch back process, or some to the suitable process) to remove the conductive material from over the second etch stop layer 324, thereby forming the heater contacts 118, 120 from the conductive material.

As shown in cross-sectional view 1800 of FIG. 18, a second dielectric layer 326 is deposited over the second etch stop layer 324. In some embodiments, the second dielectric layer 326 comprises silicon dioxide, silicon nitride, or some other suitable material and is deposited by a CVD process, a PVD process, an ALD process, or some other suitable process.

As shown in cross-sectional view 1900 of FIG. 19, the second dielectric layer 326 is etched to form an opening 1902 in the second dielectric layer 326. Opening 1902 uncovers the top surfaces of the heater contacts 118, 120. In some embodiments, a masking layer 1904 is formed over the second dielectric layer 326 and the etching is performed according to the masking layer 1904. In some embodiments, the masking layer 1904 comprises photoresist or some other suitable material. In some embodiments, the etching comprises a dry etching or some other suitable process.

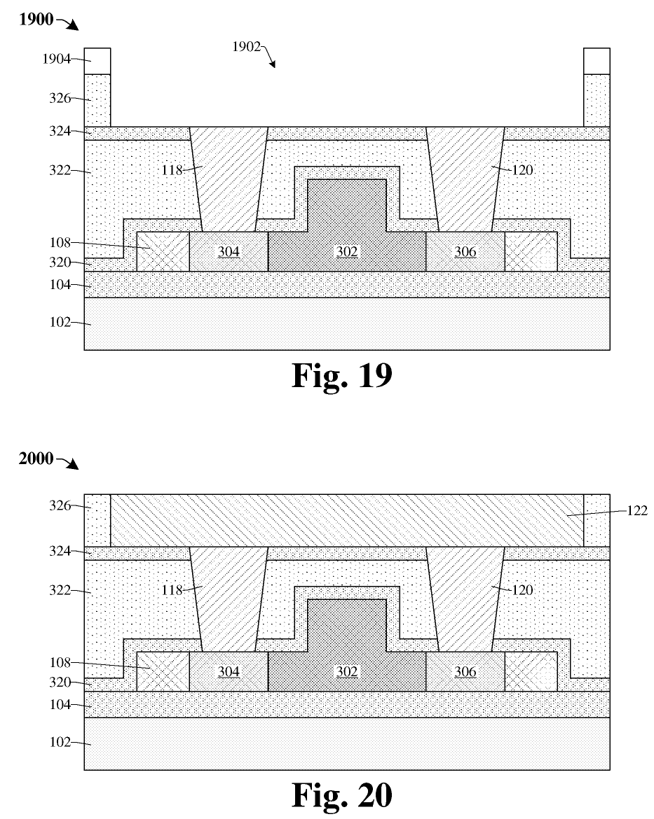

As shown in cross-sectional view 2000 of FIG. 20, the heater line 122 is formed in opening 1902. The heater line 122 is coupled to the heater contacts 118, 120. In some embodiments, the heater line 122 is formed by depositing a conductive material (e.g., copper, aluminum, titanium nitride, tungsten, or some other suitable material) over the second dielectric layer 326 and in opening 1902, and performing a planarization process to remove the conductive material from over the second dielectric layer 326, thereby forming the heater line 122 from the conductive material.

In some embodiments in which an active device is formed along the waveguide, the heater line 122 comprises two separate conductive lines (e.g., conductive lines 512, 514 of FIG. 5) to prevent an electrical short between the oppositely doped regions of the active device. In such embodiments, the etching illustrated in FIG. 19 forms two separate openings for the two separate conductive lines, the conductive material is deposited in the separate openings, and the planarization is performed to form the separate conductive lines from the conductive material.

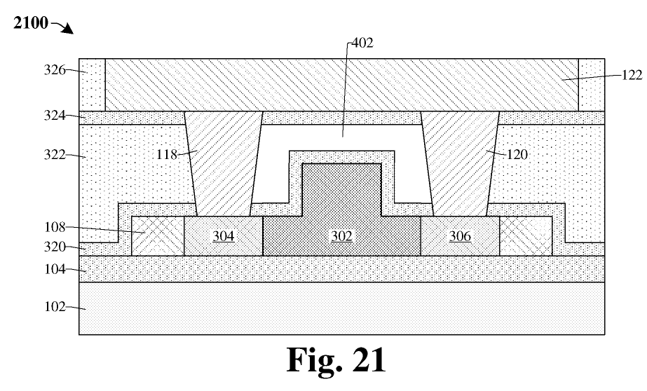

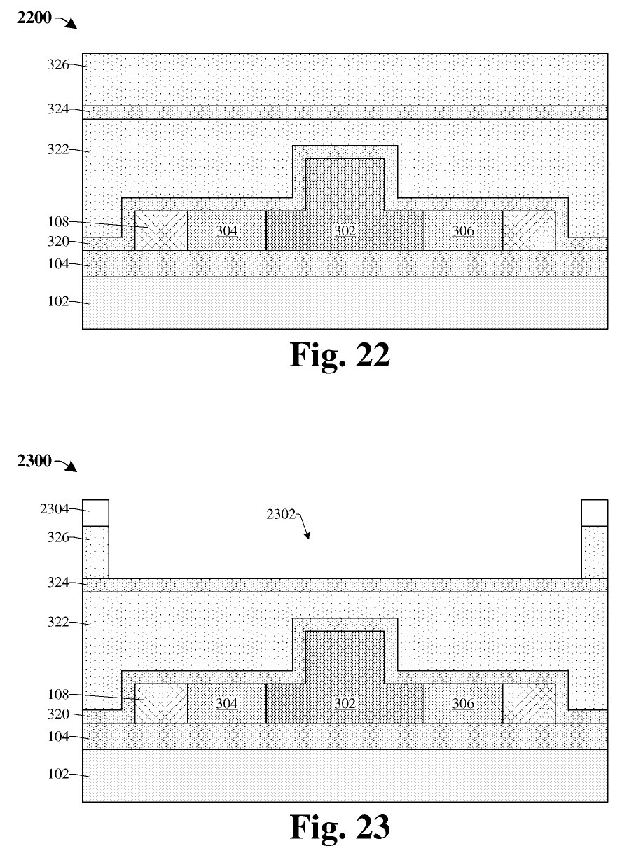

As shown in cross-sectional view 2100 of FIG. 21, in some embodiments, an upper cavity 402 is formed between the ridge portion 112 and the heater line 122 and between the ridge portion 112 and the heater contacts 118, 120. In some embodiments, forming the upper cavity 402 comprises forming a sacrificial layer (not shown) over the semiconductor waveguide layer 108 (e.g., over the first etch stop layer 320 at the ridge portion 112) and removing the sacrificial layer after the heater line 122 is formed on the heater contacts 118, 120. In some embodiments, the first etch stop layer 320 and the second etch stop layer 324 further delimit the upper cavity 402.

FIGS. 22-26 illustrate cross-sectional views 2200-2600 of some other embodiments of a method for forming the heater over the waveguide. The method illustrated in FIGS. 22-26 may be referred to as a dual damascene type method.

As shown in cross-sectional view 2200 of FIG. 22, the first etch stop layer 320 is conformally deposited over the semiconductor waveguide layer 108, the first dielectric layer 322 is deposited over the first etch stop layer 320, the second etch stop layer 324 is deposited over the first dielectric layer, and the second dielectric layer 326 is deposited over the second etch stop layer 324.

As shown in cross-sectional view 2300 of FIG. 23, the second dielectric layer 326 is etched to form an opening 2302 in the second dielectric layer 326. In some embodiments, a masking layer 2304 is formed over the second dielectric layer 326 and the etching is performed according to the masking layer 2304. In some embodiments, the masking layer 2304 comprises photoresist or some other suitable material. In some embodiments, the etching comprises a dry etching or some other suitable process.

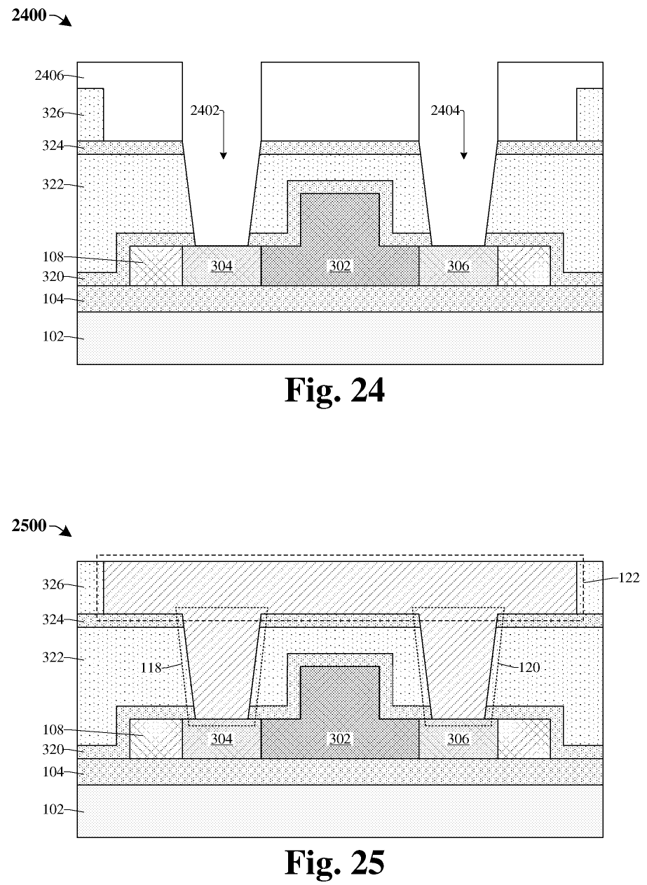

As shown in cross-sectional view 2400 of FIG. 24, the second etch stop layer 324, the first dielectric layer 322, and the first etch stop layer 320 are etched to form a first opening 2402 and a second opening 2404 in the second etch stop layer 324, the first dielectric layer 322, and the first etch stop layer 320. The second opening 2402 and the third opening 2302 extend from opening 2302 to the base portion 110 of the semiconductor waveguide layer 108 and uncover parts of the base portion 110.

In some embodiments, a masking layer 2406 is formed over the second etch stop layer 324 and the etching is performed according to the masking layer 2406. In some embodiments, the masking layer 2406 comprises photoresist or some other suitable material. In some embodiments, the etching comprises a dry etching or some other suitable process.

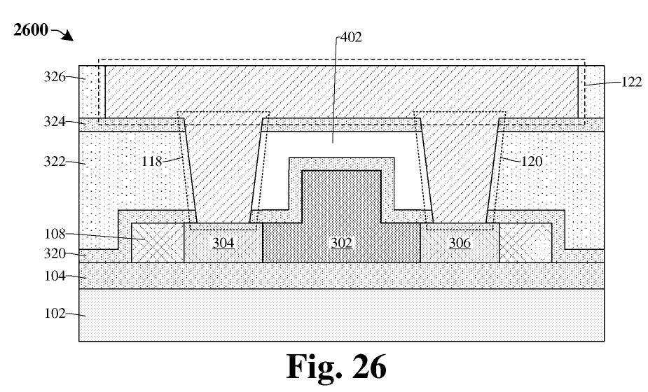

As shown in cross-sectional view 2500 of FIG. 25, the heater contacts 118, 120 are formed in openings 2402, 2404 and the heater line 122 is formed in opening 2302. In some embodiments, the heater contacts 118, 120 and the heater line 122 are formed by depositing a conductive material (e.g., copper, aluminum, titanium nitride, tungsten, or some other suitable material) over the second dielectric layer 326 and in openings 2402, 2404, 2302, and performing a planarization process to remove the conductive material from over the second dielectric layer 326, thereby forming the heater contacts 118, 120 and the heater line 122 from the conductive material.

In some embodiments in which an active device is disposed along the waveguide, the heater line 122 comprises two separate conductive lines (e.g., conductive lines 512, 514 of FIG. 5) to prevent an electrical short between the oppositely doped regions of the active device. In such embodiments, the etching illustrated in FIG. 23 forms two separate openings for the two separate conductive lines.

As shown in cross-sectional view 2600 of FIG. 26, in some embodiments, the upper cavity 402 is formed between the ridge portion 112 and the heater line 122 and between the ridge portion 112 and the heater contacts 118, 120. In some embodiments, forming the upper cavity 402 comprises forming a sacrificial layer (not shown) over the semiconductor waveguide layer 108 and removing the sacrificial layer after the heater contacts 118, 120 and heater line 122 are formed.

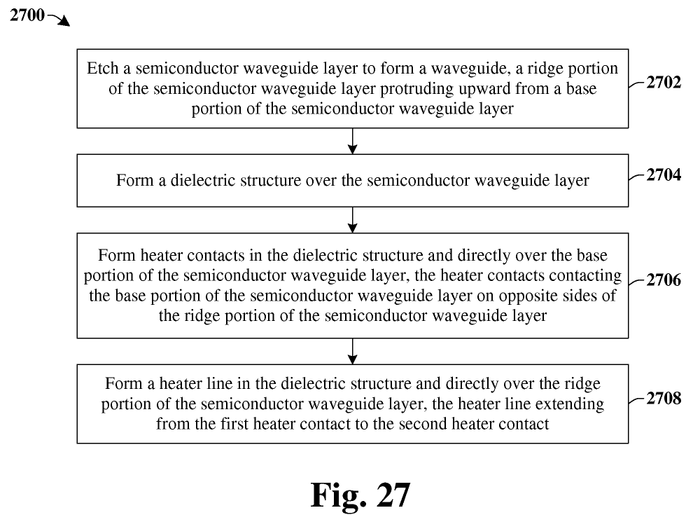

FIG. 27 illustrates a flow diagram of some embodiments of a method 2700 for forming a photonic integrated chip comprising a heater over and contacting a waveguide. While method 2700 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At block 2702, a semiconductor waveguide layer is etched to form a waveguide. A ridge portion of the semiconductor waveguide layer protrudes upward from a base portion of the semiconductor waveguide layer after the etching. FIG. 13 illustrates a cross-sectional view 1300 of some embodiments corresponding to block 2702.

At block 2704, a dielectric structure is formed over the semiconductor waveguide layer. FIGS. 15, 18, and 22 illustrate cross-sectional views 1500, 1800, and 2200, respectively, of some embodiments corresponding to block 2704.

At block 2706, heater contacts are formed in the dielectric structure and directly over the base portion of the semiconductor waveguide layer. The heater contacts contact the base portion of the semiconductor waveguide layer on opposite sides of the ridge portion of the semiconductor waveguide layer. FIGS. 17 and 25 illustrate cross-sectional views 1700 and 2500, respectively, of some embodiments corresponding to block 2706.

At block 2708, a heater line is formed in the dielectric structure and directly over the ridge portion of the semiconductor waveguide layer. The heater line extends from the first heater contact to the second heater contact. FIGS. 20 and 25 illustrate cross-sectional views 2000 and 2500, respectively, of some embodiments corresponding to block 2708.

Thus, the present disclosure relates to a heater over a semiconductor waveguide and contacting the semiconductor waveguide on opposite sides of a ridge portion of the semiconductor waveguide to improve a control of the temperature of the waveguide.

Accordingly, in some embodiments, the present disclosure relates to an integrated chip including a substrate, a semiconductor waveguide layer, a conductive heater line, a first heater contact, and a second heater contact. The semiconductor waveguide layer is over the substrate. A base portion of the semiconductor waveguide layer extends laterally over the substrate. A ridge portion of the semiconductor waveguide layer protrudes upward from the base portion. The conductive heater line is spaced over the ridge portion of the semiconductor waveguide layer. The first heater contact and the second heater contact extend from the conductive heater line to the base portion of the semiconductor waveguide layer on opposite sides of the ridge portion of the semiconductor waveguide layer.

In other embodiments, the present disclosure relates to an integrated chip including a substrate, a dielectric structure, a first heater contact, a second heater contact, and a conductive heater line. The semiconductor waveguide layer is over the substrate. The dielectric structure is over the semiconductor waveguide layer. The first heater contact and the second heater contact are over the semiconductor waveguide layer. A ridge portion of the semiconductor waveguide layer protrudes upward from a base portion of the semiconductor waveguide layer directly between the first heater contact and the second heater contact. The conductive heater line extends along the dielectric structure, directly over the ridge portion of the semiconductor waveguide layer, and between the first heater contact and the second heater contact. The first heater contact and the second heater contact extend through the dielectric structure and contact the base portion of the semiconductor waveguide layer.

In yet other embodiments, the present disclosure relates to a method for forming an integrated chip. The method includes etching a semiconductor waveguide layer to delimit a base portion of the semiconductor waveguide layer extending laterally over a substrate and to delimit a ridge portion of the semiconductor waveguide layer protruding upward from the base portion. One or more dielectric layers is/are deposited over the semiconductor waveguide layer. The one or more dielectric layers is/are etched to form a first opening and a second opening in the one or more dielectric layers on opposite sides of the ridge portion of the semiconductor waveguide layer. The first opening and the second opening uncover a first part and a second part of the base portion of the semiconductor waveguide layer, respectively. The one or more dielectric layers is/are etched to form a third opening in the one or more dielectric layers. The third opening is over the first and second openings and is directly over the ridge portion of the semiconductor waveguide layer. A conductive material is deposited in the first and second openings to form a first heater contact in the first opening and to form a second heater contact in the second opening. A conductive material is deposited in the third opening to form a conductive heater line in the third opening and on the first and second heater contacts.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated chip comprising:
a substrate;
a semiconductor waveguide layer over the substrate, a base portion of the semiconductor waveguide layer extending laterally over the substrate and a ridge portion of the semiconductor waveguide layer protruding upward from the base portion;
a conductive heater line spaced over the ridge portion of the semiconductor waveguide layer; and
a first heater contact and a second heater contact extending from the conductive heater line to the base portion of the semiconductor waveguide layer on opposite sides of the ridge portion of the semiconductor waveguide layer.

2. The integrated chip of claim 1, wherein the semiconductor waveguide layer includes a first doped region having a first doping type in the base portion of the semiconductor waveguide layer, wherein the semiconductor waveguide layer includes a second doped region having the first doping type in the base portion of the semiconductor waveguide layer, wherein the first heater contact contacts the first doped region, and wherein the second heater contact contacts the second doped region.

3. The integrated chip of claim 2, wherein the semiconductor waveguide layer includes a third doped region having the first doping type in the ridge portion of the semiconductor waveguide layer and directly between the first doped region and the second doped region, wherein a doping concentration of the first doped region and a doping concentration of the second doped region are greater than a doping concentration of the third doped region.

4. The integrated chip of claim 1, wherein the base portion is delimited by a first upper surface, a second upper surface, a first sidewall, and a second sidewall of the semiconductor waveguide layer, wherein the ridge portion is delimited by a top surface, a third sidewall, and a fourth sidewall of the semiconductor waveguide layer, wherein the third sidewall is laterally spaced from the first heater contact, wherein the fourth sidewall is laterally spaced from the second heater contact, and wherein the top surface is vertically spaced from the conductive heater line.

5. The integrated chip of claim 4, further comprising:
a dielectric layer directly between the top surface of the semiconductor waveguide layer and the conductive heater line, directly between the third sidewall of the semiconductor waveguide layer and the first heater contact, and directly between the fourth sidewall of the semiconductor waveguide layer and the second heater contact.

6. The integrated chip of claim 4, wherein a cavity filled with air is directly between the top surface of the semiconductor waveguide layer and the conductive heater line, directly between the third sidewall of the semiconductor waveguide layer and the first heater contact, and directly between the fourth sidewall of the semiconductor waveguide layer and the second heater contact.

7. The integrated chip of claim 6, wherein the top surface, the third sidewall, the fourth sidewall, the first upper surface, and the second upper surface of the semiconductor waveguide layer delimit the cavity, wherein a sidewall of the first heater contact, a sidewall of the second heater contact, and a lower surface of the conductive heater line further delimit the cavity.

8. The integrated chip of claim 1, wherein a bottom surface of the semiconductor waveguide layer and one or more surfaces of the substrate delimit a cavity directly under the ridge portion of the semiconductor waveguide layer.

9. The integrated chip of claim 1, wherein the ridge portion of the semiconductor waveguide layer extends in a closed ring, wherein the first heater contact and the second heater contact contact the base portion outside of the closed ring, the integrated chip further comprising:
a third heater contact extending from the conductive heater line to the base portion of the semiconductor waveguide layer, wherein the third heater contact contacts the base portion inside of the closed ring, wherein the third heater contact is directly between the first heater contact and the second heater contact.

10. The integrated chip of claim 1, wherein the ridge portion is a first ridge portion, wherein the conductive heater line is a first conductive heater line, and wherein a second ridge portion of the semiconductor waveguide layer protrudes upward from the base portion and is laterally spaced from the first ridge portion, the integrated chip further comprising:
a second conductive heater line spaced over the second ridge portion of the semiconductor waveguide layer; and
a third heater contact and a fourth heater contact extending from the second conductive heater line to the base portion of the semiconductor waveguide layer on opposite sides of the second ridge portion of the semiconductor waveguide layer.

11. An integrated chip comprising:
a substrate;
a semiconductor waveguide layer over the substrate;
a dielectric structure over the semiconductor waveguide layer;
a first heater contact and a second heater contact over the semiconductor waveguide layer, wherein a ridge portion of the semiconductor waveguide layer protrudes upward from a base portion of the semiconductor waveguide layer between the first heater contact and the second heater contact; and
a conductive heater line extending along the dielectric structure, over the ridge portion of the semiconductor waveguide layer, and between the first heater contact and the second heater contact,
wherein the first heater contact and the second heater contact extend through the dielectric structure and contact the base portion of the semiconductor waveguide layer.

12. The integrated chip of claim 11, wherein the ridge portion of the semiconductor waveguide layer is laterally spaced from the first heater contact in a first direction, laterally spaced from the second heater contact in a second direction, and vertically spaced from the conductive heater line.

13. The integrated chip of claim 11, wherein the semiconductor waveguide layer includes a first doped region having a first doping type in the base portion of the semiconductor waveguide layer and coupled to the first heater contact, wherein the semiconductor waveguide layer includes a second doped region having a second doping type, different than the first doping type, in the base portion of the semiconductor waveguide layer and coupled to the second heater contact,
wherein the conductive heater line includes a first conductive line and a second conductive line, the second conductive line spaced from, and electrically isolated from, the first conductive line, the first conductive line coupled to the first heater contact and the second conductive line coupled to the second heater contact.

14. The integrated chip of claim 11, wherein the conductive heater line extends continuously from the first heater contact to the second heater contact.

15. The integrated chip of claim 11, further comprising:
a barrier layer extending along a sidewall of the first heater contact, a lower surface of the conductive heater line, and a sidewall of the second heater contact, the barrier layer directly between the first heater contact and the ridge portion, directly between the second heater contact and the ridge portion, and directly between the conductive heater line and the ridge portion.

16. The integrated chip of claim 11, wherein the ridge portion, the first heater contact, the second heater contact, and the conductive heater line are elongated in a common direction.

17. A method for forming an integrated chip, the method comprising:
etching a semiconductor waveguide layer to delimit a base portion of the semiconductor waveguide layer extending laterally over a substrate and to delimit a ridge portion of the semiconductor waveguide layer protruding upward from the base portion;
depositing one or more dielectric layers over the semiconductor waveguide layer;
etching the one or more dielectric layers to form a first opening and a second opening in the one or more dielectric layers on opposite sides of the ridge portion of the semiconductor waveguide layer, the first opening and the second opening uncovering a first part and a second part of the base portion of the semiconductor waveguide layer, respectively;
etching the one or more dielectric layers to form a third opening in the one or more dielectric layers, the third opening over the first and second openings and over the ridge portion of the semiconductor waveguide layer;
depositing a conductive material in the first and second openings to form a first heater contact in the first opening and to form a second heater contact in the second opening; and
depositing a conductive material in the third opening to form a conductive heater line in the third opening and on the first and second heater contacts.

18. The method of claim 17, further comprising:
doping the semiconductor waveguide layer to form a first doped region having a first doping type in the base portion of the semiconductor waveguide layer, to form a second doped region having the first doping type in the base portion of the semiconductor waveguide layer, and to form a third doped region in the ridge portion of the semiconductor waveguide layer and directly between the first doped region and the second doped region, wherein a doping concentration of the first doped region and a doping concentration of the second doped region are greater than a doping concentration of the third doped region,
wherein the first opening and the second opening are formed directly over the first doped region and the second doped region, respectively.

19. The method of claim 17, further comprising:
forming a cavity directly under the ridge portion of the ridge portion of the semiconductor waveguide layer, the cavity delimited by a bottom surface of the semiconductor waveguide layer and one or more surfaces of the substrate.

20. The method of claim 17, further comprising:
forming a cavity between the ridge portion and the conductive heater line and between the ridge portion and the first and second heater contacts.
